(19) United States
(12) Patent Application Publication
(10) Pub. No.: US 2025/0093785 A1
(43) Pub. Date: Mar. 20, 2025

(54) METHOD OF GENERATING DRAWING DATA, DRAWING DATA GENERATION DEVICE, DRAWING DATA GENERATION PROGRAM, EXPOSURE SYSTEM, AND DEVICE MANUFACTURING METHOD

(71) Applicant: NIKON CORPORATION, Tokyo (JP)

(72) Inventor: Yuho KANAYA, Tokyo (JP)

(73) Assignee: NIKON CORPORATION, Tokyo (JP)

(21) Appl. No.: 18/968,070

(22) Filed: Dec. 4, 2024

Related U.S. Application Data
(63) Continuation of application No. PCT/JP2022/022827, filed on Jun. 6, 2022.

(51) Int. Cl. G03F 7/00

(52) U.S. Cl. CPC G03F 7/70508; G03F 7/70683

(57) ABSTRACT

There is provided a method of generating drawing data representing a drawing pattern to be formed by a spatial light modulator to form a predetermined exposure pattern on a substrate with exposure light via the spatial light modulator, the method being implemented by a computer, the method including generating design data representing a design pattern corresponding to the predetermined exposure pattern by using a function defined by a user, and generating the drawing data of the drawing pattern by converting the design data.

### CROSS-REFERENCE TO RELATED APPLICATION

This application is a continuation application of the prior International Patent Application No. PCT/JP2022/022827, filed on Jun. 6, 2022, the entire contents of which are incorporated herein by reference.

### FIELD

The present disclosure relates to a method of generating drawing data, a drawing data generation device, a drawing data generation program, an exposure system, and a device manufacturing method.

### BACKGROUND

A so-called maskless exposure device that generates a variable pattern on the object plane of the projection optical system using a spatial light modulator (SLM) with an array of multiple micromirrors, each with a variable tilt angle, has been proposed as disclosed in, for example, U.S. Pat. No. 6,747,783.

It is desired to reduce the time required to generate data representing patterns to be generated by a spatial light modulator.

### SUMMARY

In a first aspect of the present disclosure, there is provided a method of generating drawing data representing a drawing pattern to be formed by a spatial light modulator to form a predetermined exposure pattern on a substrate with exposure light via the spatial light modulator, the method being implemented by a computer, the method including: generating first drawing data from design data, the design data representing a design pattern corresponding to the predetermined exposure pattern, the design pattern including a second pattern that is repeatedly arranged, the second pattern including a plurality of first patterns that are repeatedly arranged, the first drawing pattern corresponding to one of the plurality of first patterns; generating second drawing data representing a second drawing pattern corresponding to the second pattern, based on the first drawing data that has been generated and first information indicating a repetition manner of the plurality of first patterns; and generating the drawing data representing the drawing pattern, based on the second drawing data that has been generated and second information indicating a repetition manner of the second pattern.

In a second aspect of the present disclosure, there is provided a method of generating drawing data representing a drawing pattern to be formed by a spatial light modulator to form a predetermined exposure pattern on a substrate with exposure light via the spatial light modulator, the method being implemented by a computer, the method including: acquiring first information indicating a repetition manner of a first pattern that is repeatedly arranged in a design pattern corresponding to the predetermined exposure pattern; receiving specification of second drawing data to be used as first drawing data representing a first drawing pattern corresponding to the first pattern; and generating the drawing data of the drawing pattern by using the second drawing data that has been specified and the first information.

In a third aspect of the present disclosure, there is provided a method of generating drawing data representing a drawing pattern to be formed by a spatial light modulator to form a predetermined exposure pattern on a substrate with exposure light via the spatial light modulator, the method being implemented by a computer, the method including: generating design data representing a design pattern corresponding to the predetermined exposure pattern by using a function defined by a user; and generating the drawing data of the drawing pattern by converting the design data.

In a fourth aspect of the present disclosure, there is provided a method of generating drawing data representing a drawing pattern to be formed by a spatial light modulator to form a predetermined exposure pattern on a substrate with exposure light via the spatial light modulator, the method being implemented by a computer, the method including: acquiring drawing data of each of a plurality of different drawing patterns that are generated in advance and have a size smaller than the drawing pattern; and generating the drawing data of the drawing pattern by arranging the drawing data of the plurality of different drawing patterns in accordance with a predetermined rule.

In a fifth aspect of the present disclosure, there is provided a drawing data generation device that generates drawing data representing a drawing pattern to be formed by a spatial light modulator to form a predetermined exposure pattern on a substrate with exposure light via the spatial light modulator, the drawing data generation device including: a first generation unit configured to generate first drawing data from design data, the design data representing a design pattern corresponding to the predetermined exposure pattern, the design pattern including a second pattern that is repeatedly arranged, the second pattern including a plurality of first patterns that are repeatedly arranged, the first drawing pattern corresponding to one of the plurality of first patterns; a second generation unit configured to generate second drawing data representing a second drawing pattern corresponding to the second pattern, based on the first drawing data that has been generated and first information indicating a repetition manner of the plurality of first patterns; and a third generation unit configured to generate the drawing data representing the drawing pattern, based on the second drawing data that has been generated and second information indicating a repetition manner of the second pattern.

In a sixth aspect of the present disclosure, there is provided a drawing data generation device that generates drawing data representing a drawing pattern to be formed by a spatial light modulator to form a predetermined exposure pattern on a substrate with exposure light via the spatial light modulator, the drawing data generation device including: an acquisition unit configured to acquire first information indicating a repetition manner of a first pattern repeatedly arranged in a design pattern corresponding to the predetermined exposure pattern; a reception unit configured to receive specification of second drawing data to be used as first drawing data representing a first drawing pattern corresponding to the first pattern; and a generation unit configured to generate the drawing data of the drawing pattern by using the second drawing data that has been specified and the first information.

In a seventh aspect of the present disclosure, there is provided a drawing data generation device that generates drawing data representing a drawing pattern to be formed by a spatial light modulator to form a predetermined exposure pattern on a substrate with exposure light via the spatial light modulator, the drawing data generation device including: a first generation unit configured to generate design data representing a design pattern corresponding to the predetermined exposure pattern by using a function defined by a user; and a second generation unit configured to generate the drawing data of the drawing pattern by converting the design data.

In an eighth aspect of the present disclosure, there is provided a drawing data generation device that generates drawing data representing a drawing pattern to be formed by a spatial light modulator to form a predetermined exposure pattern on a substrate with exposure light via the spatial light modulator, the drawing data generation device including: an acquisition unit configured to acquire drawing data of each of a plurality of different drawing patterns that are generated in advance and have a size smaller than the drawing pattern; and a generation unit configured to generate the drawing data of the drawing pattern by arranging the drawing data of the plurality of different drawing patterns in accordance with a predetermined rule.

In a nineth aspect of the present disclosure, there is provided a non-transitory computer-readable storage medium storing a drawing data generation program for generating drawing data representing a drawing pattern to be formed by a spatial light modulator to form a predetermined exposure pattern on a substrate with exposure light via the spatial light modulator, the drawing data generation program causing a computer to execute a process, the process including: generating first drawing data from design data, the design data representing a design pattern corresponding to the predetermined exposure pattern, the design pattern including a second pattern that is repeatedly arranged, the second pattern including a plurality of first patterns that are repeatedly arranged, the first drawing pattern corresponding to one of the plurality of first patterns; generating second drawing data representing a second drawing pattern corresponding to the second pattern, based on the first drawing data that has been generated and first information indicating a repetition manner of the plurality of first patterns; and generating the drawing data representing the drawing pattern, based on the second drawing data that has been generated and second information indicating a repetition manner of the second pattern.

In a tenth aspect of the present disclosure, there is provided a non-transitory computer-readable storage medium storing a drawing data generation program for generating drawing data representing a drawing pattern to be formed by a spatial light modulator to form a predetermined exposure pattern on a substrate with exposure light via the spatial light modulator, the drawing data generation program causing a computer to execute a process, the process including: acquiring first information indicating a repetition manner of a first pattern that is repeatedly arranged in a design pattern corresponding to the predetermined exposure pattern; receiving specification of second drawing data to be used as first drawing data representing a first drawing pattern corresponding to the first pattern; and generating the drawing data of the drawing pattern by using the second drawing data that has been specified and the first information.

In an eleventh aspect of the present disclosure, there is provided a non-transitory computer-readable storage medium storing a drawing data generation program for generating drawing data representing a drawing pattern to be formed by a spatial light modulator to form a predetermined exposure pattern on a substrate with exposure light via the spatial light modulator, the drawing data generation program causing a computer to execute a process, the process including: generating design data representing a design pattern corresponding to the predetermined exposure pattern by using a function defined by a user; and generating the drawing data of the drawing pattern by converting the design data.

In a twelfth aspect of the present disclosure, there is provided a non-transitory computer-readable storage medium storing a drawing data generation program for generating drawing data representing a drawing pattern to be formed by a spatial light modulator to form a predetermined exposure pattern on a substrate with exposure light via the spatial light modulator, the drawing data generation program causing a computer to execute a process, the process including: acquiring drawing data of each of a plurality of different drawing patterns that are generated in advance and have a size smaller than the drawing pattern; and generating the drawing data of the drawing pattern by arranging the drawing data of the plurality of different drawing patterns in accordance with a predetermined rule.

In a thirteenth aspect of the present disclosure, there is provided an exposure system including: the above drawing data generation device; and an exposure device that includes a spatial light modulator, causes the spatial light modulator to form the drawing pattern based on the drawing data generated by the drawing data generation device, and forms the predetermined exposure pattern on a substrate with exposure light via the spatial light modulator.

In a fourteenth aspect of the present disclosure, there is provided a device manufacturing method including: generating the drawing data of the drawing pattern by using the above drawing data generation device; causing the spatial light modulator to form the drawing pattern based on the drawing data, and forming the predetermined exposure pattern on a substrate with exposure light via the spatial light modulator; and processing a surface of the substrate using the predetermined exposure pattern formed on the substrate as a mask.

In a fifteenth aspect of the present disclosure, there is provided a method of generating drawing data representing a drawing pattern to be formed by a spatial light modulator to form a predetermined exposure pattern on a substrate with exposure light via the spatial light modulator, the method being implemented by a computer, the method including: displaying design data representing a design pattern corresponding to the predetermined exposure pattern; identifying, from the design pattern, a second partial design pattern that is the same as a first partial design pattern in a specified region that is specified using an image of the designed data that has been displayed; generating first partial drawing data corresponding to the first partial design pattern in the specified region; and setting the first partial drawing data that has been generated as second partial drawing data corresponding to the second partial design pattern that has been specified.

The configuration of the embodiments described below may be modified appropriately, and at least one or some of the components may be substituted for other components. Further, the constituent elements whose arrangement is not particularly limited are not limited to the arrangement disclosed in the embodiments, and can be arranged at positions where the functions can be achieved.

### BRIEF DESCRIPTION OF DRAWINGS

FIG. 1 is a schematic view illustrating an exposure system in accordance with a first embodiment;

FIG. 2 illustrates an example of a spatial light modulator;

FIG. 3A illustrates an example of a hardware configuration of a data generation device, and FIG. 3B is a functional block diagram of the data generation device;

FIG. 4A is a view for describing a target pattern, a design pattern, and a drawing pattern, and FIG. 4B is a view for describing stripe data and an exposure pattern;

FIG. 5 is a flowchart (part 1) illustrating an example of a process executed by the data generation device;

FIG. 6 is a flowchart (part 2) illustrating the example of the process executed by the data generation device;

FIG. 7 illustrates an example of the design pattern displayed on a display unit by a display control unit;

FIG. 8A is a diagram for describing the area of a main pattern, FIG. 8B illustrates an example of repetition pattern information of the main pattern, and FIG. 8C and FIG. 8D illustrate examples of repetition arrangement information of the main pattern;

FIG. 9 illustrates an example of the main pattern displayed in an enlarged manner on the display unit;

FIG. 10A to FIG. 10L are diagrams for describing sub patterns;

FIG. 11 is a flowchart illustrating an example of a sub-pattern process;

FIG. 12 is an enlarged view of a region where sub patterns are arranged;

FIG. 13 illustrates a specified sub pattern by hatching;

FIG. 14A illustrates an example of repetition pattern information generated when step S27 in FIG. 6 is completed, and FIG. 14B illustrates an example of repetition arrangement information;

FIG. 15 is a diagram for describing a section;

FIG. 16 illustrates an example of a section including a repetition pattern and a pattern other than the repetition pattern;

FIG. 17A illustrates a configuration of an exposure system in accordance with a second embodiment, and FIG. 17B illustrates a configuration of an exposure system in accordance with a variation of the second embodiment;

FIG. 18 is a diagram for describing a metalens;

FIG. 19 illustrates a configuration of an exposure system in accordance with a third embodiment; and

FIG. 20 illustrates small patterns.

### DESCRIPTION OF EMBODIMENTS

### First Embodiment

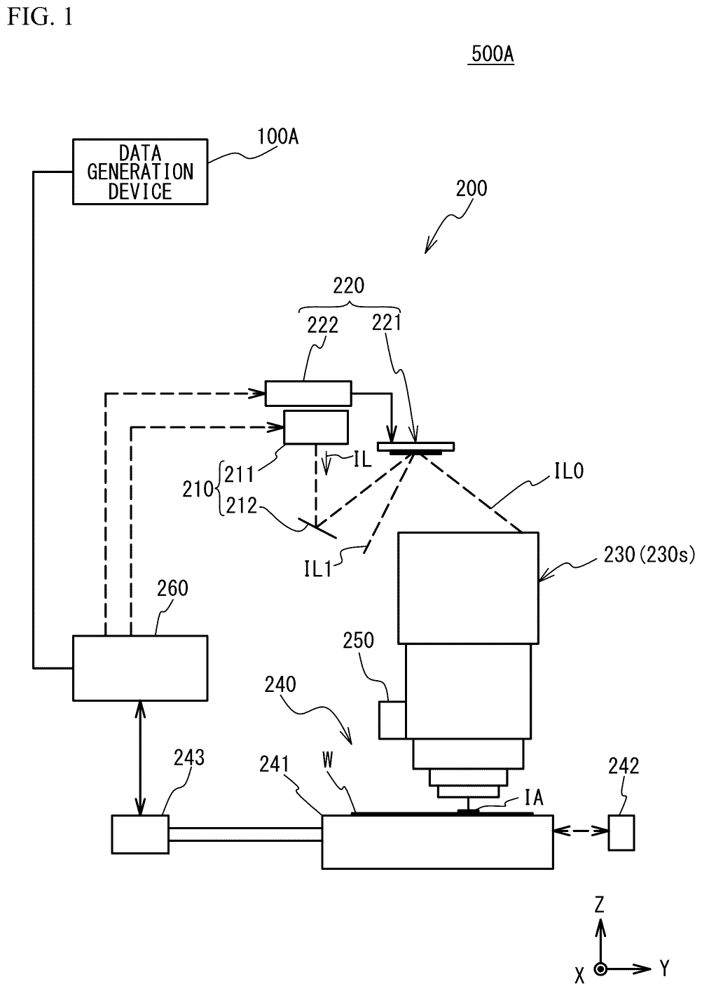

An exposure system 500A in accordance with a first embodiment will be described based on FIG. 1 to FIG. 16.

FIG. 1 is a schematic view illustrating the exposure system 500A in accordance with the first embodiment. As illustrated in FIG. 1, the exposure system 500A includes an exposure device 200 and a data generation device 100A.

### Exposure Device 200

The exposure device 200 is an exposure device that uses a spatial light modulator (SLM) that modulates exposure light in accordance with control by an exposure control unit 260, which will be described later.

As illustrated in FIG. 1, the exposure device 200 includes an illumination system 210, a pattern generation device 220, a projection optical system 230, a stage device 240, an alignment detection system 250, and the exposure control unit 260. In the description of the exposure device 200, two directions orthogonal to each other in a horizontal plane are defined as an X direction and a Y direction, and a vertical direction is defined as a Z direction. Further, the rotation (inclination) directions about the X axis, the Y axis, and the Z axis are defined as a θx direction, a θy direction, and a θz direction, respectively.

The illumination system 210 includes a light source unit (not illustrated), an illumination optical system 211, and a reflection mirror 212. The light source unit includes, for example, a solid-state laser light source (a DFB semiconductor laser, a fiber laser, or the like). The illumination optical system 211 includes a shaping optical system, an optical integrator, a field stop, and a relay lens system (none of which are illustrated) for changing the illumination condition.

The pattern generation device 220 generates a pattern to be projected onto a photosensitive layer of a wafer W placed on a stage 241 (to be described later) of the stage device 240 in accordance with control by the exposure control unit 260. The pattern generation device 220 includes a spatial light modulator (SLM) 221 and a drive unit 222.

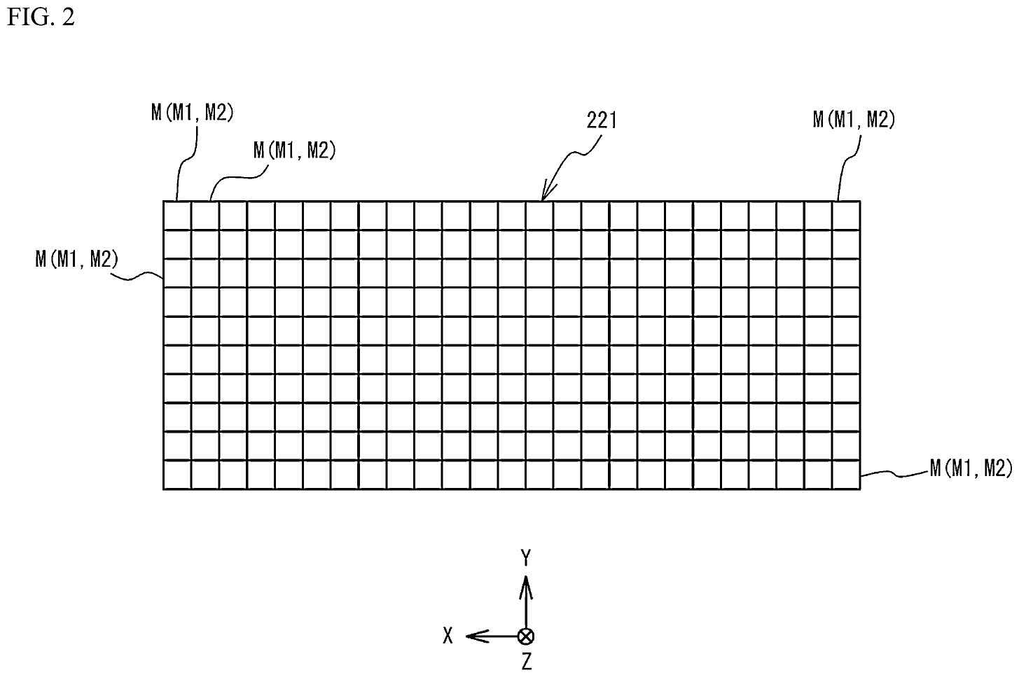

FIG. 2 illustrates an example of the SLM 221. As illustrated in FIG. 2, the SLM 221 is, for example, a digital mirror device (DMD), and has a plurality of micromirror mechanisms M arranged in a matrix (two dimensional, array-manner) in the X-Y plane. Each of the micromirror mechanisms M includes a micromirror M1 and a drive mechanism M2 provided on the opposite side from the reflecting surface of the micromirror M1. The drive mechanism M2 rotates the micromirror M1 around an axis extending in the X direction.

The drive unit 222 drives the drive mechanism M2 of each of the micromirror mechanisms M in accordance with a control signal from the exposure control unit 260, and switches the micromirror MI between an ON state (ON position) and an OFF state (OFF position).

When the illumination light IL from the illumination system 210 enters the micromirror M1 in the ON state, the zeroth-order diffracted light IL0 of the illumination light IL enters the projection optical system 230. On the other hand, when the illumination light IL from the illumination system 210 enters the micromirror M1 in the OFF state, the zeroth-order diffracted light IL1 of the illumination light IL reaches a non-exposure optical path off the projection optical system 230. The pattern generation device 220 gives a pattern to the illumination light IL by setting each of the micromirrors M1 to either the ON state or the OFF state.

The SLM 221 is not limited to a type of switching between the ON state and the OFF state by tilting the micromirror, and may be a type of generating a phase difference by tilting the micromirror or a type of generating a phase difference by moving the micromirror up and down. The SLM 221 is not limited to the DMD, and may be, for example, a magneto optic spatial light modulator (MOSLM). Further, the SLM 221 has been described as a reflective type that reflects the illumination light IL, but the SLM 221 may be a transmissive type that transmits the illumination light IL, or a diffractive type that diffracts the illumination light IL. The SLM 221 may be any spatial light modulator as long as it can spatially and temporally modulate the illumination light IL.

The projection optical system 230 projects an image of the light modulation surface of the SLM 221 onto the wafer W placed on the stage 241 at a reduced projection magnification β (for example, β= 1/200, 1/400, 1/500, or the like). That is, an exposure pattern is formed on the wafer W by the energy beam through the pattern generation device 220. The projection magnification of the projection optical system 230 may be equal magnification or enlarged magnification. The optical system includes a barrel 230s and a plurality of optical elements (not illustrated) arranged in a predetermined positional relationship inside the barrel 230s.

The stage device 240 includes the stage (substrate stage) 241, a laser interferometer 242, and a stage drive unit 243.

The stage 241 holds the wafer W via a wafer holder (not illustrated) provided in the center of the upper surface thereof. The stage 241 is movable in the X direction, the Y direction, and the Z direction by the stage drive unit 243, and is rotatable around an axis extending in the Z direction.

The laser interferometer 242 emits a length measurement beam onto a reflection surface provided on each of the end surfaces of the stage 241 in the X direction and the Y direction, thereby constantly detecting the positions of the stage 241 in the X direction, the Y direction, and the θz direction with a resolution of, for example, about 0.5 nm to 1 nm.

The stage drive unit 243 drives the stage 241 in accordance with a control signal from the exposure control unit 260.

The alignment detection system 250 is arranged on a side surface of the projection optical system 230. In the present embodiment, an imaging alignment sensor is used as the alignment detection system 250. The detailed configuration of the alignment detection system 250 is disclosed in, for example, U.S. Pat. No. 5,637,129.

The alignment detection system 250 detects street lines or position detection marks formed on the wafer W. The detection results of the street lines or the position detection marks by the alignment detection system 250 are output to the exposure control unit 260.

The exposure control unit 260 controls the pattern generation device 220 based on the stripe data (described in detail later) generated by the data generation device 100A, and also controls the operations of the illumination system 210, the stage device 240, and the like, and projects the image of the pattern generated by the SLM 221 onto the wafer W held by the stage 241 through the projection optical system 230.

When the SLM 221 is illuminated with the illumination light IL from the illumination system 210, the illumination light IL reflected by the micromirrors M1 in the ON state of the SLM 221, i.e., the illumination light IL patterned by the SLM 221, enters the projection optical system 230, and a reduced image (partially inverted image) of the pattern is formed in the projection area IA on the wafer W held by the stage 241.

In the present embodiment, the exposure control unit 260 performs exposure by a step-and-scan method. The exposure control unit 260 moves the stage 241 at an appropriate speed during the scan exposure, and scrolls the pattern generated by the SLM 221 in synchronization with the movement of the stage (that is, changes the shape of the pattern generated by the SLM 221).

As the exposure device 200 having the above configuration, the exposure device disclosed in U.S. Pat. No. 8,089,616, U.S. Patent Application Publication No. 2020/00257205, or International Publication No. 2005/081034 may be used.

### Data Generation Device 100A

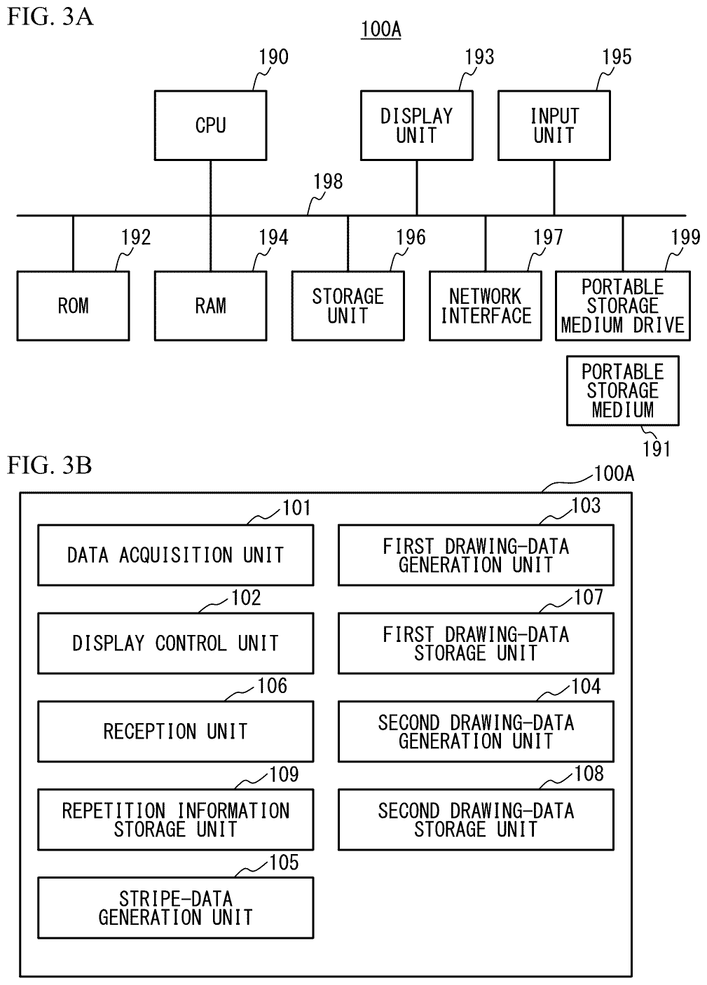

Next, the data generation device 100A will be described. The data generation device 100A is, for example, a personal computer, a server, or the like. FIG. 3A illustrates an example of a hardware configuration of the data generation device 100A.

As illustrated in FIG. 3A, the data generation device 100A includes a central processing unit (CPU) 190, a read only memory (ROM) 192, a random access memory (RAM) 194, a storage unit (a solid state drive (SSD) or the like) 196, a display unit 193, an input unit 195, a network interface 197, and a portable storage medium drive 199. The display unit 193 includes a liquid crystal display or the like, and the input unit 195 includes a keyboard, a mouse, a touch panel, or the like. These components of the data generation device 100A are connected to a bus 198.

FIG. 3B is a functional block diagram of the data generation device 100A. As illustrated in FIG. 3B, the data generation device 100A includes a data acquisition unit 101, a display control unit 102, a reception unit 106, a repetition information storage unit 109, a first drawing-data generation unit 103, a first drawing-data storage unit 107, a second drawing-data generation unit 104, a second drawing-data storage unit 108, and a stripe-data generation unit 105.

The data acquisition unit 101, the display control unit 102, the reception unit 106, the first drawing-data generation unit 103, the second drawing-data generation unit 104, and the stripe-data generation unit 105 are implemented by the CPU 190 executing programs (including a drawing-data generation program) stored in the ROM 192 or the storage unit 196, or programs (including the drawing-data generation program) read from a portable storage medium 191 by the portable storage medium drive 199. The repetition information storage unit 109, the first drawing-data storage unit 107, and the second drawing-data storage unit 108 are implemented by, for example, the storage unit 196. The functions of the data acquisition unit 101, the display control unit 102, the reception unit 106, the first drawing-data generation unit 103, the second drawing-data generation unit 104, and the stripe-data generation unit 105 may be implemented by an integrated circuit such as an application specific integrated circuit (ASIC), a field programmable gate array (FPGA), or a graphics processing unit (GPU).

The data acquisition unit 101 acquires target pattern data representing an exposure pattern to be formed on the wafer W (hereinafter, referred to as a target pattern) and design data representing a design pattern (also referred to as a polygon mask) corresponding to the exposure pattern obtained by performing optical proximity correction (OPC) on the target pattern data. The design data representing the design pattern is, for example, data in an OASIS or GDSII format.

The display control unit 102 performs processes such as displaying the design pattern represented by the design data acquired by the data acquisition unit 101 on the display unit 193.

The reception unit 106 receives a user operation on the design pattern displayed on the display unit 193. The reception unit 106 generates repetition pattern information and repetition arrangement information (details will be described later) based on an operation received from the user, and stores the repetition pattern information and the repetition arrangement information in the repetition information storage unit 109.

The first drawing-data generation unit 103 and the second drawing-data generation unit 104 generate drawing data representing a pattern (hereinafter, referred to as a drawing pattern) to be generated by the SLM 221 using the design data and the repetition pattern information and the repetition arrangement information stored in the repetition information storage unit 109. The drawing data generated by the first drawing-data generation unit 103 and the second drawing-data generation unit 104 will be described in detail later.

The first drawing-data storage unit 107 stores the drawing data generated by the first drawing-data generation unit 103, and the second drawing-data storage unit 108 stores the drawing data generated by the second drawing-data generation unit 104.

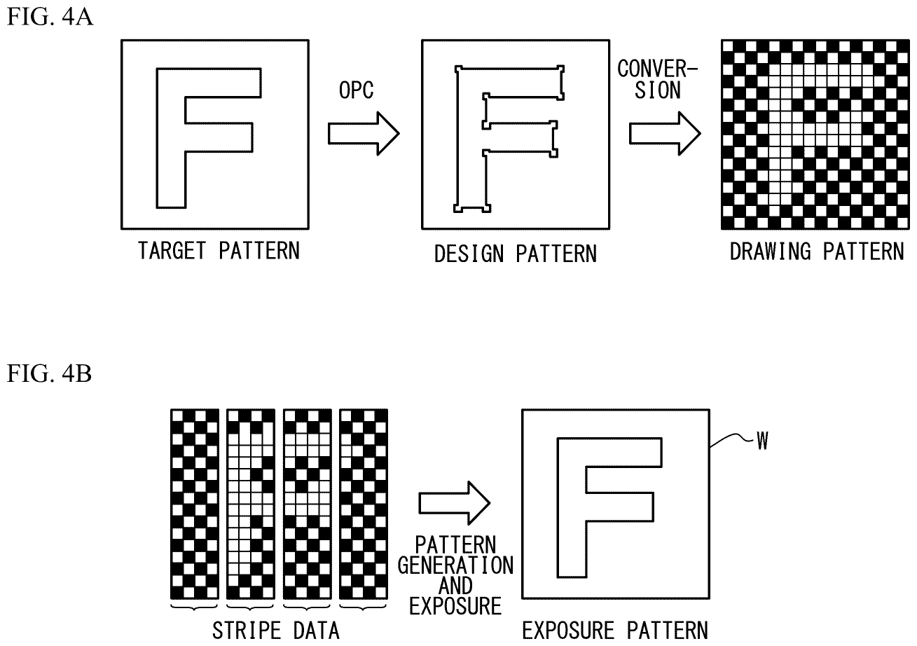

Before describing the process executed by the data generation device 100A, each pattern and data will be described. FIG. 4A is a diagram for describing the target pattern, the design pattern, and the drawing pattern, and FIG. 4B is a diagram for describing the stripe data and the exposure pattern.

The target pattern illustrated on the left side of FIG. 4A is a pattern to be formed on the wafer W.

In an exposure device such as a scanning stepper or a stepper used in a lithography process for manufacturing a device (electronic device or micro device) such as a semiconductor device, the line width of a pattern formed on a wafer W after exposure may vary depending on the pitch, or the position of the end of the pattern may change, because of the optical proximity effect (OPE). Therefore, when the SLM 221 is caused to generate a pattern based on the drawing pattern generated by converting the target pattern, a desired pattern may not be formed on the wafer W.

Therefore, to correct the change in the pattern due to the OPE characteristics, OPC is performed to cancel the change due to the OPE characteristics by correcting the line width of the target pattern in advance or adding an auxiliary pattern. A pattern obtained by performing OPC on the target pattern is a design pattern (illustrated in the center of FIG. 4A). As illustrated in FIG. 4A, the design pattern is slightly different from the target pattern. The design data representing the design pattern is data in a vector format.

When the design data is converted into data in a bitmap format (also referred to as a raster format), drawing data is obtained. The drawing data is data representing the drawing pattern illustrated on the right side of FIG. 4A. Each pixel of the drawing pattern is represented by either white or black. In FIG. 4A, for example, a white pixel corresponds to the ON state of the mirror of the SLM 221, and a black pixel corresponds to the OFF state of the mirror.

Using the drawing data generated in this manner, the stripe data generation unit 105 generates stripe data to be used for controlling the pattern generation device 220. The stripe data is data obtained by arranging the drawing data at a desired position and extracting a part of the drawing data in accordance with the number of pixels of the SLM 221, as illustrated on the left side of FIG. 4B.

The SLM 221 is caused to generate a pattern based on the stripe data, and the generated pattern is projected onto the wafer W, whereby an exposure pattern substantially equal to the target pattern is formed (exposed) on the wafer W, as illustrated on the right side of FIG. 4B.

When the drawing data is obtained by converting the design data, it may take a long time to generate the drawing data due to imaging calculation or the like. In the first embodiment, the time required to generate drawing data is reduced by the process described below.

### Process Executed by Data Generation Device 100A

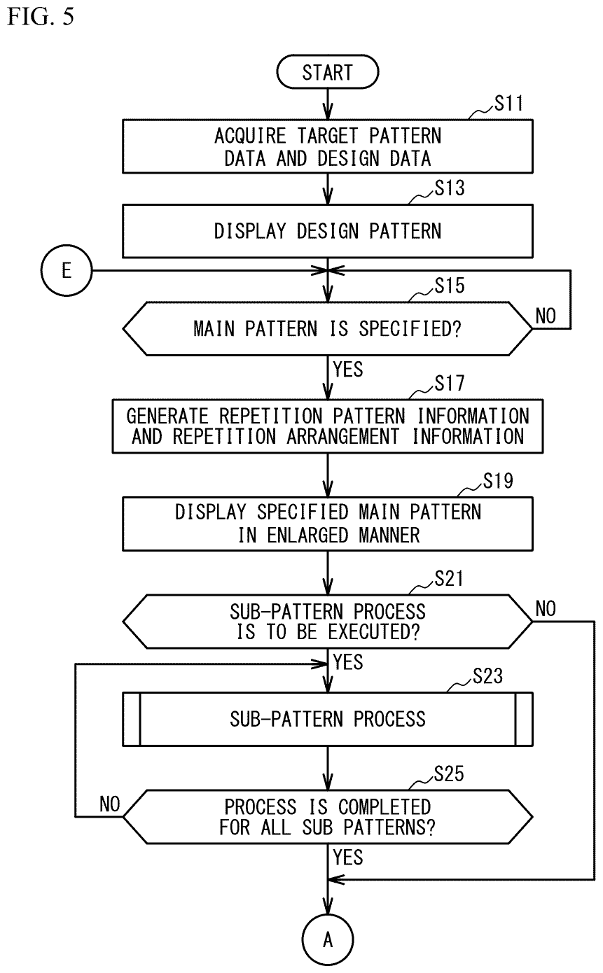

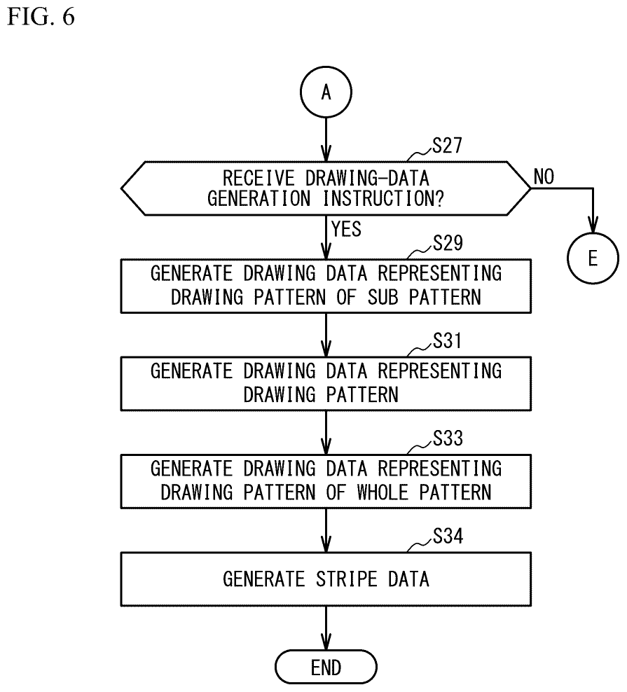

FIG. 5 and FIG. 6 are flowcharts illustrating an example of a process executed by the data generation device 100A.

The process of FIG. 5 is started when the drawing data generation program is executed, for example, by the user launching the drawing data generation software.

In the process of FIG. 5, the data acquisition unit 101 acquires target pattern data and design data (step S11). For example, when the user specifies the files of the target pattern data and the design data, the data acquisition unit 101 reads the specified files and acquires the target pattern data and the design data.

When the data acquisition unit 101 acquires the target pattern data and the design data, the display control unit 102 displays the design pattern on the display unit 193 based on the design data (step S13).

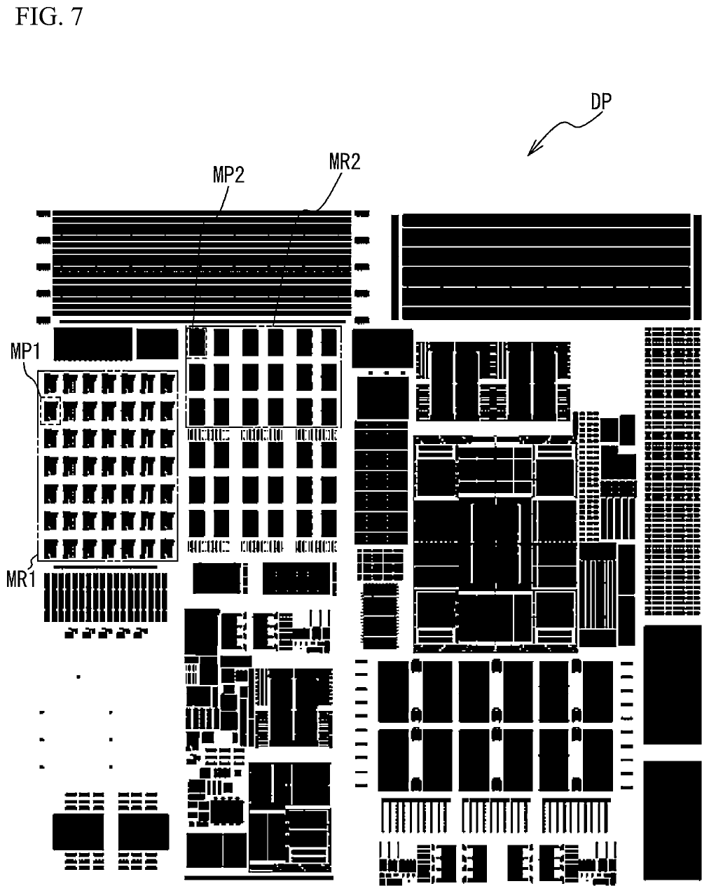

FIG. 7 illustrates an example of a design pattern DP displayed on the display unit 193 by the display control unit 102. As illustrated in FIG. 7, the design pattern DP includes a plurality of regions where the same pattern is repeatedly arranged. For example, a pattern MP1 is repeatedly arranged in a region MR1, and a pattern MP2 is repeatedly arranged in a region MR2. The patterns MP1 and MP2 are referred to as main patterns MP1 and MP2 for convenience. In the following description, a pattern repeatedly arranged in a design pattern may be referred to as a repetition pattern.

Returning to FIG. 5, the reception unit 106 waits until a main pattern that is repeatedly arranged is specified (step S15/NO). The user can specify the main pattern MP1 by enclosing the main pattern MP1 with a rectangular frame by a drag operation of the mouse on the screen on which the design pattern DP is displayed. In this case, the rectangular frame can be said to be a specified region.

When the main pattern is specified (step S15/YES), the reception unit 106 generates the repetition pattern information and the repetition arrangement information for the specified main pattern (step S17). The repetition pattern information is information for extracting, from the design pattern, a pattern repeatedly arranged in the design pattern, and the repetition arrangement information is information indicating the repetition manner of the pattern (how the repeatedly arranged pattern is arranged).

The process of step S17 will be described in detail. First, the reception unit 106 determines the exact area of the main pattern MP1 by referring to the patterns arranged around the specified main pattern MP1. Then, the reception unit 106 identifies information necessary for extracting the main pattern MP1 from the design pattern based on the exact area of the main pattern MP1.

Then, the reception unit 106 searches for the same pattern as the specified main pattern MP1 from the design pattern. For example, the reception unit 106 determines whether a pattern arranged around the specified main pattern MP1 is the same as the specified main pattern MP1, and continues the search until the same pattern as the specified main pattern MP1 is not identified. In the generation of drawing data described below, since the pasting operation is performed on the drawing data, which is raster data, the search is performed under the condition that the repetition interval is an integer multiple of the pixel size. In the first embodiment, the search for the same pattern as the specified main pattern MP1 is performed using the target pattern. This is because, as described above, the same patterns in the target patten may have different shapes in the design pattern after OPC. The search may be performed using the design pattern instead of the target pattern. In this case, the data acquisition unit 101 may not necessarily acquire the target pattern in step S11.

The reception unit 106 generates the repetition arrangement information based on the search result.

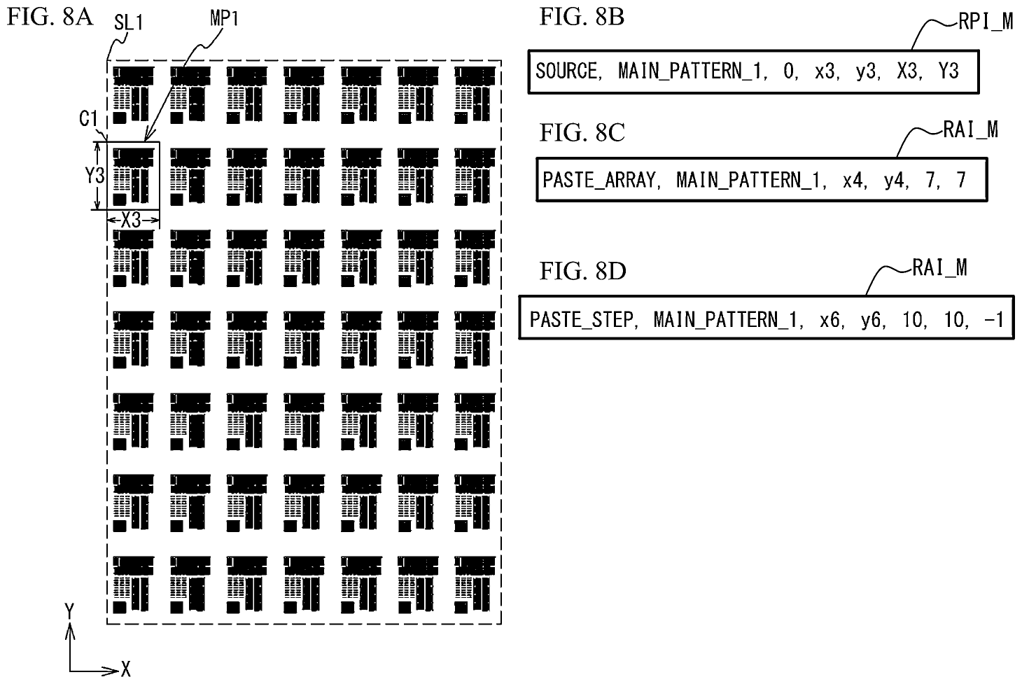

FIG. 8A is a diagram for describing the area of the main pattern MP1, FIG. 8B illustrates an example of the repetition pattern information of the main pattern MP1, and FIG. 8C and FIG. 8D illustrate examples of the repetition arrangement information of the main pattern MP1.

For example, it is assumed that the coordinates of the upper left vertex C1 of the rectangle indicating the area of the main pattern MP1 illustrated in FIG. 8A are (x3, y3), and that the length of the side in the X direction is X3 and the length of the side in the Y direction is Y3.

In this case, the reception unit 106 generates the repetition pattern information RPI_M as illustrated in FIG. 8B. As illustrated in FIG. 8B, the repetition pattern information RPI_M is data in a comma-separated format, for example. In the first embodiment, the repetition pattern information RPI_M includes a generation instruction of the drawing pattern, a name for uniquely identifying the repetition pattern, a tier in which the repetition pattern exists, and information indicating the area of the repetition pattern. The repetition pattern information RPI_M is not limited to data in a comma-separated format, and may be data in another format (for example, data in a tab-separated format or structured data such as Extensible Markup Language (XML) or JavaScript Object Notation (JSON)). The format may be a binary format instead of a text format.

For example, in FIG. 8B, “SOURCE” at the leftmost is an instruction to convert a design pattern into a drawing pattern. The second from the left “MAIN_PATTERN_1” is a name for uniquely identifying the main pattern MP1. The third value from the left indicates a tier in which a repetition pattern exists, and for example, “0” indicates that the repetition pattern is a main pattern. Further, “1” indicates that the repetition pattern is a sub pattern (details will be described later). The fourth to seventh values from the left are information indicating the area of the repetition pattern. For example, the fourth and fifth values from the left indicate the X coordinate and the Y coordinate of the upper left vertex C1 of the rectangular area of the main pattern MP1 illustrated in FIG. 8A, respectively, and the sixth and seventh values indicate the lengths in the X direction and the Y direction of the rectangular area of the main pattern MP1, respectively.

On the other hand, the repetition arrangement information RAI_M illustrated in FIG. 8C includes, for example, an arrangement method of the repetition pattern, the name of the pattern to be repeatedly arranged, and information indicating details of the arrangement method of the repetition pattern.

Here, in the example of FIG. 8A, the repetition pattern (main pattern MP1) is arranged in a 7×7 array in the X and Y directions, and the X coordinate and the Y coordinate of the start position SL1 of the region where the main pattern MP1 is repeatedly arranged are x4 and y4, respectively.

In this case, the repetition arrangement information RAI_M is, for example, “PASTE_ARRAY, MAIN_PATTERN_1, x4, y4, 7, 7” illustrated in FIG. 8C.

In the repetition arrangement information RAI_M of FIG. 8C, “PASTE_ARRAY” at the first from the left indicates that the repetition pattern specified by the second item from the left is arranged in an array.

The third to sixth values from the left are information detailing how the repetition pattern is arranged. The third and fourth values from the left indicate the X coordinate and the Y coordinate indicating the start position from which the repetition patten is arranged, respectively, the fifth value indicates the number of rows (the number of patterns arranged in the Y direction), and the sixth value indicates the number of columns (the number of patterns arranged in the X direction).

The method of arranging the repetition pattern is not limited to the array form (“PASTE_ARRAY”), and for example, the repetition pattern may be arranged in a stepped form. In this case, for example, as illustrated in FIG. 8D, the first value from the left is, for example, “PASTE_STEP”. The third and fourth values from the left indicate the X coordinate and the Y coordinate indicating the start position from which the repetition pattern is arranged, the fifth value indicates the number of steps, the sixth value indicates the number of repetition patterns arranged in the first step, and the seventh value indicates the number of repetition patterns decreased per step when the value is negative and indicates the number of repetition patterns increased per step when the value is positive.

The repetition pattern information and the repetition arrangement information generated in this manner are stored in the repetition information storage unit 109.

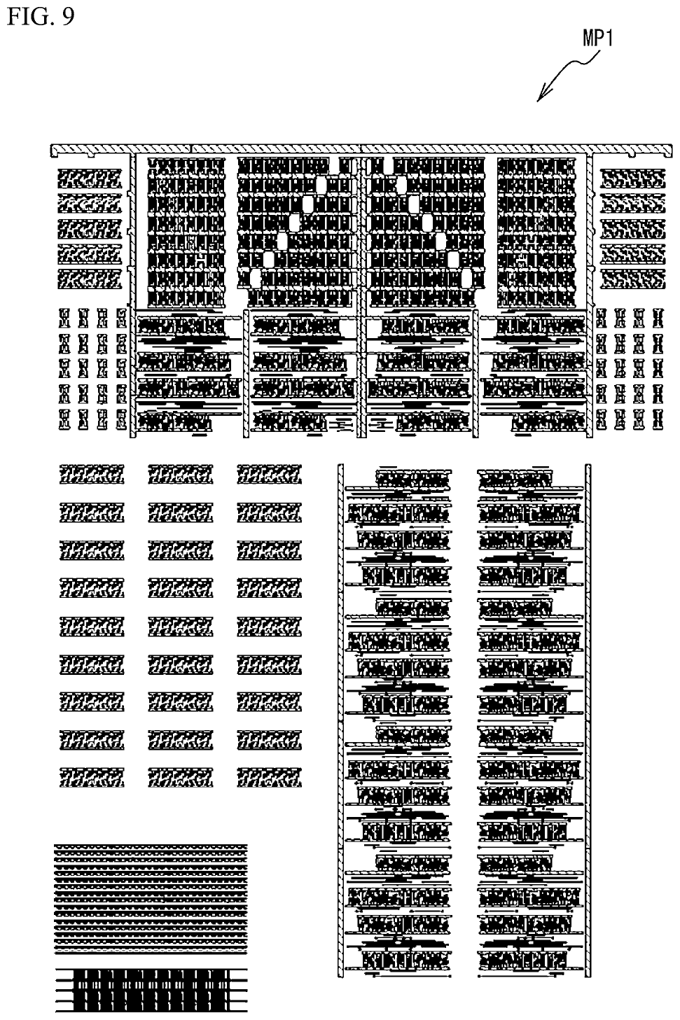

Returning to FIG. 5, after the completion of step S17, the display control unit 102 displays the specified main pattern on the display unit 193 in an enlarged manner (step S19). FIG. 9 illustrates an example of the main pattern MP1 displayed in an enlarged manner on the display unit 193. As illustrated in FIG. 9, the main pattern MP1 also includes a region where the same pattern is repeatedly arranged. In the following description, a pattern repeatedly arranged in the main pattern is referred to as a sub pattern. The sub pattern as well as the main pattern is an examples of the repetition pattern.

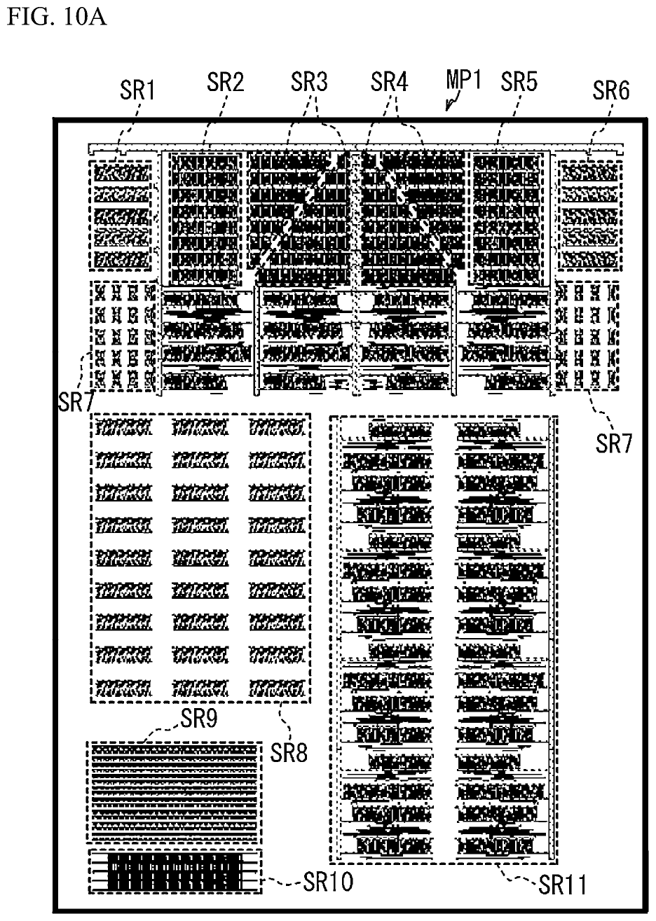

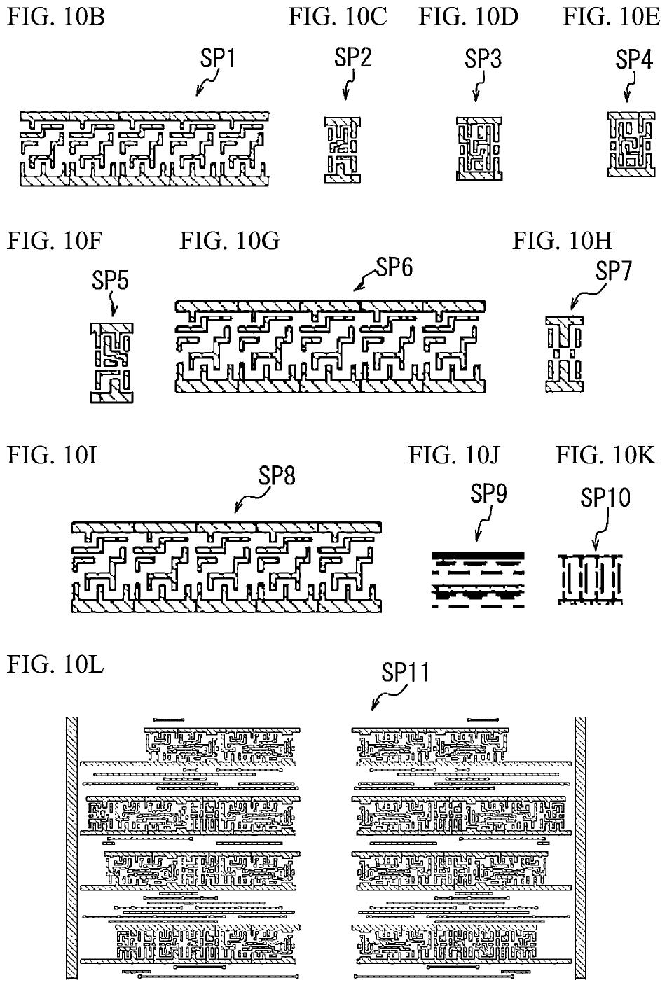

FIG. 10A to FIG. 10L are diagrams for describing the sub patterns. FIG. 10A illustrates the main pattern MP1, and FIG. 10B to FIG. 10L illustrate the sub patterns.

In the main pattern MP1 illustrated in FIG. 10A, a sub pattern SP1 illustrated in FIG. 10B is repeatedly arranged in a region SR1, a sub pattern SP2 illustrated in FIG. 10C is repeatedly arranged in a region SR2, and a sub pattern SP3 illustrated in FIG. 10D is repeatedly arranged in a region SR3.

In addition, a sub pattern SP4 illustrated in FIG. 10E is repeatedly arranged in a region SR4, a sub pattern SP5 illustrated in FIG. 10F is repeatedly arranged in a region SR5, and a sub pattern SP6 illustrated in FIG. 10G is repeatedly arranged in a region SR6. A sub pattern SP7 illustrated in FIG. 10H is repeatedly arranged in a region SR7, a sub pattern SP8 illustrated in FIG. 10L is repeatedly arranged in a region SR8, and a sub pattern SP9 illustrated in FIG. 10J is repeatedly arranged in a region SR9. A sub pattern SP10 illustrated in FIG. 10K is repeatedly arranged in a region SR10, and a sub pattern SP11 illustrated in FIG. 10L is repeatedly arranged in a region SR11.

Returning to FIG. 5, after the main pattern is displayed in an enlarged manner (step S19), the reception unit 106 determines whether to execute a sub-pattern process (step S21). For example, when the user presses a “sub-pattern specification” button displayed on the screen, the reception unit 106 determines that the sub-pattern process is to be executed (step S21/YES), and executes the sub-pattern process (step S23). When the sub-pattern process is not to be executed (step S21/NO), the process proceeds to step S27 described later.

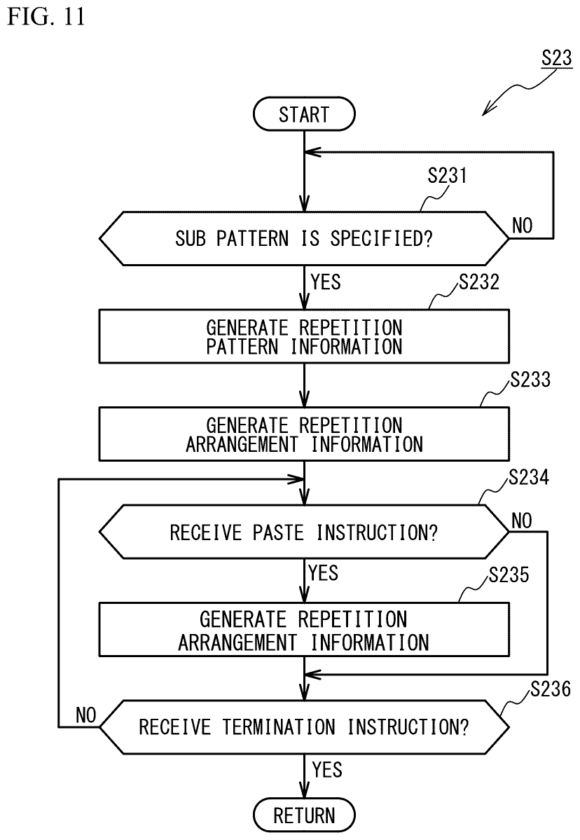

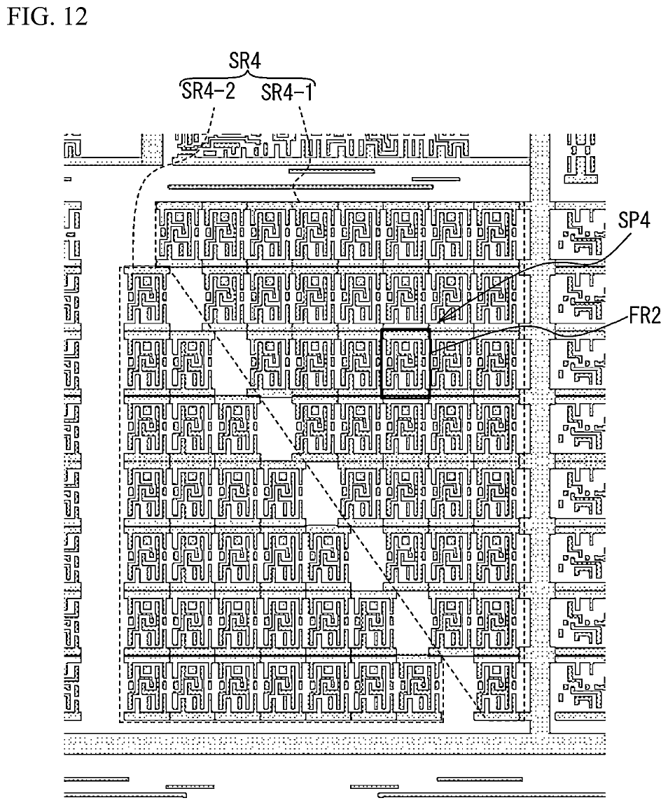

FIG. 11 is a flowchart illustrating an example of the sub-pattern process. In the process of FIG. 11, first, the reception unit 106 waits until a sub pattern is specified in the main pattern displayed in an enlarged manner (step S231/NO). When a sub pattern is specified (step S231/YES), the reception unit 106 generates the repetition pattern information for the sub pattern (step S232), and further generates the repetition arrangement information for the sub pattern (step S233). The specified sub pattern is an example of a first partial design pattern.

The processing of steps S232 and S233 will now be described using the case where the sub pattern SP4 (see FIG. 10E) in the region SR4 is specified in the main pattern MP1 illustrated in FIG. 10A.

FIG. 12 is an enlarged view of the region SR4. The user causes the display unit 193 to display the region SR4 in an enlarged manner by changing the display magnification, for example, and encloses one of the sub patterns SP4 repeatedly arranged in the region SR4 with a rectangular frame FR2 by a drag operation of the mouse as illustrated in FIG. 12. This specifies the sub pattern SP4. The rectangular frame FR2 can also be referred to as a specified region.

When the sub pattern SP4 is specified, the reception unit 106 determines the exact area of the sub pattern SP4 by referring to the patterns arranged around the specified sub pattern SP4, and generates the repetition pattern information for the sub pattern SP4, as in the case of the main pattern MP1.

Then, the reception unit 106 searches for the same pattern as the specified sub pattern SP4 around the specified sub pattern SP4, and identifies the sub pattern SP4 that is repeatedly arranged. As in the case of the main pattern, the search is performed under the condition that the repetition interval is an integral multiple of the pixel size. In the first embodiment, even when the same pattern as the specified sub pattern SP4 is searched, the target pattern is used to determine whether the pattern is the same as the specified sub pattern, as in the case of the main pattern. As in the case of the main pattern, the design pattern may be used instead of the target pattern. The same pattern as the specified sub pattern SP4 is an example of a second partial design pattern.

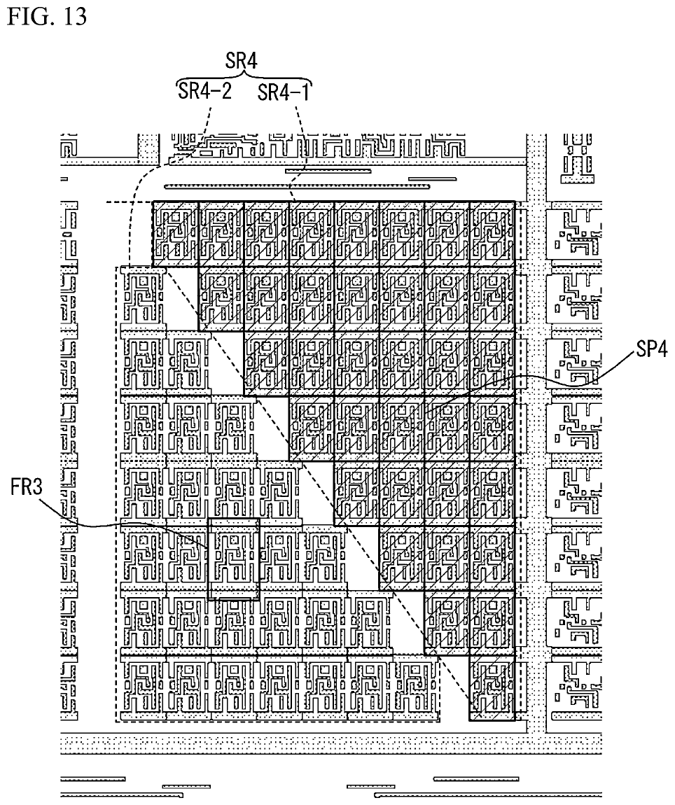

FIG. 13 illustrates the identified sub pattern SP4 by hatching. In the region SR4, the sub pattern SP4 repeatedly arranged in a region SR4-1 is identified. Since there is a blank portion between the region SR4-1 and a region SR4-2 (since the repetition is interrupted), the search process for the sub pattern SP4 is not performed in the region SR4-2.

As a result of the search process, the repetition manner of the sub pattern SP4 in the region SR4-1 can be determined, and thus the reception unit 106 generates repetition arrangement information indicating the repetition manner of the sub pattern SP4, as in the case of the main pattern MP1.

Returning to FIG. 11, when the generation of the repetition pattern information and the repetition arrangement information for the specified sub pattern is completed, the reception unit 106 determines whether a paste instruction has been received (step S234). The paste instruction is an instruction to generate the repetition arrangement information for another region different from the region for which the repetition arrangement information is generated in step S233, when the sub pattern specified in step S231 is repeatedly arranged in the another region.

For example, in FIG. 13, when the user wants to generate the repetition arrangement information of the sub pattern SP4 also for the region SR4-2, the user encloses the pattern corresponding to the sub pattern SP4, which is arranged in the region SR4-2, with a rectangular frame FR3. Alternatively, the user may determine the position of the frame FR3 by connecting the vertex of the figure inside the sub pattern SP4 and the vertex of the figure inside the frame FR3 corresponding thereto. This causes the reception unit 106 to determine that the paste instruction has been received.

When the paste instruction is received (step S234/YES), the reception unit 106 generates the repetition arrangement information for the region SR4-2 (step S235). For example, the reception unit 106 determines whether the pattern enclosed with the frame FR3 is the same as the sub pattern SP4 specified in step S231. When the pattern enclosed with the frame FR3 is the same as the sub pattern SP4 specified in step S231, the reception unit 106 searches for the same pattern as the sub pattern SP4 and identifies the sub pattern SP4 repeatedly arranged around the sub pattern SP4 enclosed with the frame FR3, as in the process for the region SR4-1. Then, the reception unit 106 determines the repetition manner of the sub pattern SP4 based on the identification result, and generates the repetition arrangement information of the sub pattern SP4 in the region SR4-2. When the pattern enclosed with the frame FR3 is not the same as the sub pattern SP4 specified in step S231, the process of step S235 is not performed, and the process proceeds to step S236.

After the process of step S235 is completed, or when the paste instruction is not received (step S234/NO), the reception unit 106 determines whether an instruction to terminate the sub-pattern process is received (step S236). When the instruction to terminate the sub-pattern process has not been received (step S236/NO), the process returns to step S234. On the other hand, when the instruction to terminate the sub-pattern process is received, the process proceeds to step S25 in FIG. 5.

The reception unit 106 determines whether the sub-pattern process has been completed for all the sub patterns included in the main pattern (step S25). For example, the reception unit 106 determines whether the sub-pattern process has been completed for all the sub patterns based on whether the user has pressed a button “end sub-pattern specification” displayed on the screen.

When the sub-pattern process has not been completed for all the sub-patterns (step S25/NO), the process returns to step S23. This allows the user to perform the sub-pattern process for the sub patterns (SP1 to SP3, SP5 to SP11) repeatedly arranged other than the sub pattern SP4.

On the other hand, when the sub-pattern process has been completed for all the sub patterns (step S25/YES), the reception unit 106 determines whether a drawing-data generation instruction has been received (FIG. 6: step S27). The reception unit 106 determines that the drawing-data generation instruction has been received, for example, when a “drawing data generation” button displayed on the screen is pressed.

When the drawing-data generation instruction has not been received (step S27/NO), the process returns to step S15. This allows the user to perform the above-described process for another main pattern (for example, the main pattern MP2) that is repeatedly arranged.

On the other hand, when the drawing-data generation instruction is received (step S27/YES), the first drawing-data generation unit 103 generates drawing-data representing the drawing pattern of the sub pattern (hereinafter, referred to as the sub-pattern drawing data) based on the repetition pattern information (step S29).

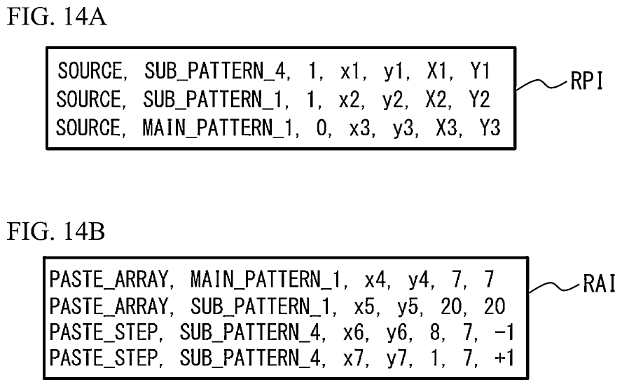

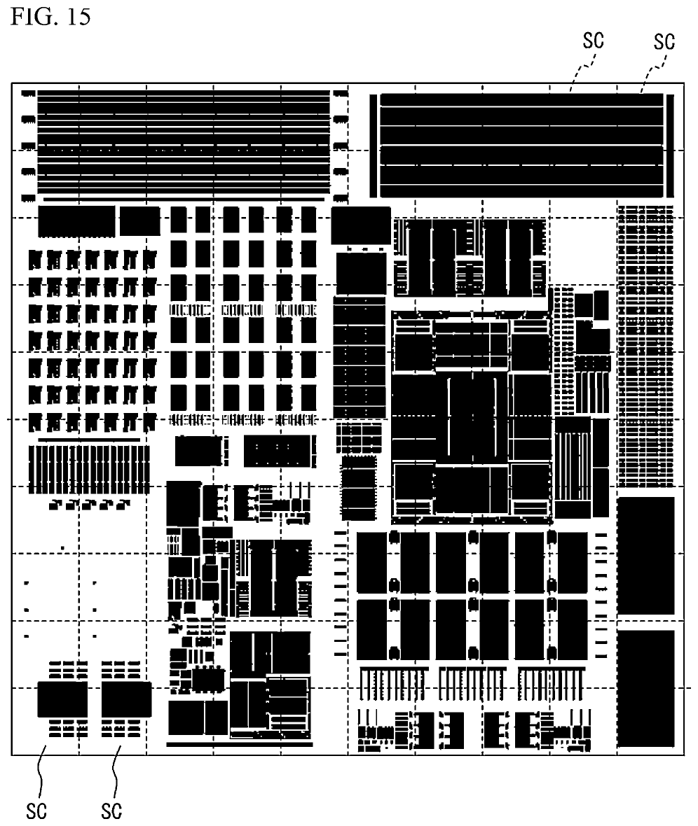

FIG. 14A illustrates an example of the repetition pattern information RPI generated at the time when step S27 is completed, and FIG. 14B illustrates an example of the repetition arrangement information RAI.

For example, the first drawing-data generation unit 103 reads the repetition pattern information RPI, and when the third value from the left indicating the tier in which the repetition pattern exists is “1” (sub pattern), the first drawing-data generation unit 103 extracts the design pattern of the sub pattern from the design pattern DP based on the fourth to seventh values from the left, and converts the extracted design pattern into the drawing pattern.

Then, the first drawing-data generation unit 103 generates drawing data representing the drawing pattern of the main pattern (hereinafter, referred to as main-pattern drawing data) based on the generated sub-pattern drawing data and the repetition arrangement information RAI of the sub pattern (step S31).

More specifically, the first drawing-data generation unit 103 generates the main-pattern drawing data by pasting the sub-pattern drawing data generated in step S29 based on the repetition arrangement information RAI of the sub pattern for the region where the sub pattern is repeatedly arranged and converting the design data for the region where the repetition pattern is not arranged.

In other words, for example, for the region SR4 where the sub pattern SP4 is repeatedly arranged, the generated drawing data of the sub pattern SP4 is used as the drawing data corresponding to the pattern identified as the same as the sub pattern SP4. In other words, for the pattern identified as the same as the sub pattern SP4, instead of converting the design data to generate the drawing data, the generated drawing data of the sub pattern SP4 is used as the drawing data for that pattern.

The drawing data of the sub pattern SP4 is allocated on the drawing-data coordinates as a part of the main-pattern drawing data based on the position of the sub pattern SP4 specified in the design pattern, and the drawing data corresponding to the pattern identified as the same as the sub pattern SP4 is allocated on the drawing-data coordinates as another part of the main-pattern drawing data based on the position of the pattern identified as the same as the sub pattern SP4 in the design pattern.

When the drawing data is generated by converting the design data, since imaging calculation or the like is performed, it may require a long time to generate the drawing data. In the first embodiment, since the drawing data of the sub pattern that have already generated is pasted for the region where the sub pattern is repeatedly arranged, it is not necessary to perform imaging calculation or the like. Therefore, the time required to generate the drawing data of the main pattern can be reduced compared with that in the case where the whole drawing data of the main pattern are generated by converting the design data.

The main-pattern drawing data generated by the first drawing-data generation unit 103 is stored in the first drawing-data storage unit 107.

Then, the second drawing-data generation unit 104 arranges the main-pattern drawing data stored in the first drawing-data storage unit 107 based on the repetition arrangement information RAI of the main pattern, thereby generating the drawing data representing the drawing pattern of the whole pattern (see FIG. 7) (hereinafter, referred to as drawing data of the whole pattern) (step S33).

In the generation of the drawing data of the whole pattern, as illustrated in FIG. 15, the whole pattern is divided into sections SC of a predetermined size, and drawing data is generated for each section SC. At this time, the second drawing-data generation unit 104 changes the method of generating the drawing data depending on the following cases: (1) a case where the repetition pattern is not included in the section, (2) a case where all the patterns included in the section are the repetition patterns, and (3) a case where the repetition pattern and the pattern other than the repetition pattern are included in the section. In the case (1), the second drawing-data generation unit 104 converts the design data to generate the drawing data in a conventional way. In the case (2), the second drawing-data generation unit 104 generates the drawing data by pasting the already generated drawing data of the repetition pattern (for example, the drawing data of the main pattern MP1) into the section SC. This eliminates the need for imaging calculation or the like, and thus the time required to generate the drawing data can be reduced compared with that in the case where the drawing data is generated by converting the design data.

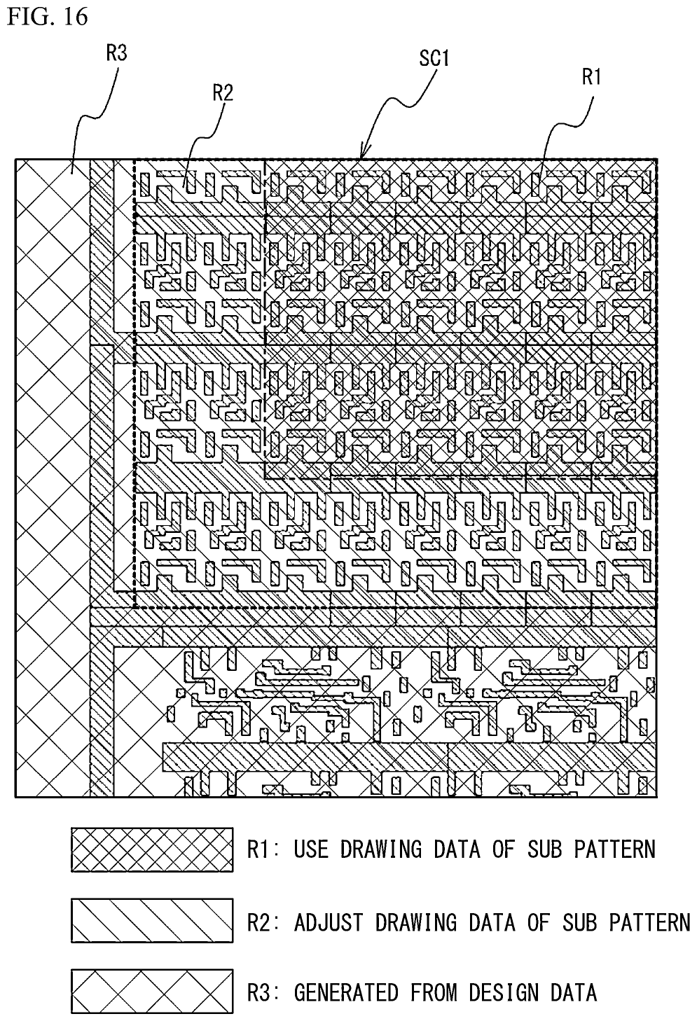

Next, the case (3) will be described with reference to FIG. 16. FIG. 16 illustrates an example of a section SC1 including a repetition pattern and a pattern other than the repetition pattern. In FIG. 16, the repetition pattern is arranged in the combined region of a region R1 and a region R2. If the drawing pattern of the repetition pattern is arranged in the regions R1 and R2 as it is, there is a possibility that the drawing pattern of the repetition pattern does not match the drawing pattern of a region R3 where the pattern other than the repetition pattern is arranged. Therefore, in the region R2 (region R2 adjacent to the region R3), which is the peripheral portion of the combined region of the regions R1 and R2 where the repetition pattern is arranged, the drawing pattern of the repetition pattern is adjusted so as to match the drawing pattern of the region R3. In this manner, an exposure pattern closer to the target pattern can be formed on the wafer W. Even when the drawing data of the main pattern is generated, the main pattern may be divided into sections of a predetermined size, and the drawing data may be generated for each section. Also, when the drawing data of the sub pattern is generated, the sub pattern may be divided into sections of a predetermined size, and the drawing data may be generated for each section.

The generated drawing data (bitmap file) of each section SC is stored in the second drawing-data storage unit 108.

After the process of step S33 is completed, the stripe-data generation unit 105 generates stripe data by combining the drawing data of each section SC stored in the second drawing-data storage unit 108 (step S34), and the process of FIG. 5 and FIG. 6 is completed. By causing the SLM 221 to generate a pattern based on the stripe data and projecting the generated pattern onto the wafer W, an exposure pattern substantially the same as the target pattern can be formed on the wafer W.

In the process of FIG. 5 and FIG. 6, when none of the main patterns includes a sub pattern, the process of step S29 is not performed, and in step S31, a design pattern in an area corresponding to the main pattern may be extracted based on the repetition pattern information RPI of the main pattern, and the drawing data may be generated by converting the extracted design pattern into the drawing pattern. In this case, the main pattern corresponds to a first partial design pattern, and the same pattern as the main pattern corresponds to a second partial design pattern.

As described above in detail, in the first embodiment, the data generation device 100A generates the drawing data representing the drawing pattern to be formed by the SLM 221 to form a predetermined exposure pattern on the wafer W with the exposure light via the SLM 221. The data generation device 100A includes: the first drawing-data generation unit 103 that generates the drawing data representing the drawing pattern of the sub pattern from the design data representing the design pattern corresponding to the predetermined exposure pattern in which a main pattern including a plurality of sub patterns repeatedly arranged is repeatedly arranged, and generates the drawing data representing the drawing pattern corresponding to the main pattern based on the generated drawing data of the sub pattern and repetition arrangement information indicating the repetition manner of the sub pattern; and the second drawing-data generation unit 104 that generates the drawing data representing the drawing pattern of the whole pattern based on the generated drawing data of the main pattern and repetition arrangement information indicating the repetition manner of the main pattern.

Since a part of the drawing data of the main pattern is generated by generating the drawing data of the sub pattern and pasting the generated drawing data of the sub pattern for the main pattern in which the same sub pattern is repeatedly arranged, the time required to generate the drawing data of the main pattern can be reduced compared with that in the case where the whole drawing data of the main pattern is generated by converting the design data. Further, since a part of the drawing data of the whole pattern is generated by pasting the generated drawing data of the main pattern for the main pattern repeatedly arranged in the whole pattern, the time required to generate the drawing data of the whole pattern can be reduced compared with that in the case where the drawing data of the whole pattern is generated by converting the design data.

In the first embodiment, the data generation device 100A includes the display control unit 102 that displays the design pattern on the display unit 193, and the reception unit 106 that receives the specification of the main pattern from the design pattern displayed on the display unit 193. The display control unit 102 displays the specified main pattern in an enlarged manner on the display unit 193, and the reception unit 106 receives the specification of the sub pattern from the main pattern displayed in an enlarged manner on the display unit 193, and generates repetition pattern information and repetition arrangement information necessary for generating the drawing pattern of the sub pattern from the design data on the basis of the specification. This allows the user to specify the main pattern and the sub pattern that are repeatedly arranged while viewing the design pattern displayed on the display unit 193. Further, when the user specifies the main pattern and the sub pattern that are repeatedly arranged, the repetition pattern information and the repetition arrangement information are automatically generated, and thus it is possible to reduce the work load of the user.

In the first embodiment, the reception unit 106 generates the repetition arrangement information for the region that includes the specified sub pattern and in which the sub pattern is repeatedly arranged. Since the reception unit 106 searches for and identifies the same pattern as the specified sub pattern and generates the repetition arrangement information, the user does not need to specify the repeatedly arranged sub pattern one by one, and the work load and the work time of the user can be reduced.

In the first embodiment, the reception unit 106 receives specification of a second region (for example, the region SR4-2) where the sub-pattern is repeatedly arranged, which is different from a first region (for example, the region SR4-1) that includes the specified sub pattern and where the sub pattern is repeatedly arranged, and generates the repetition arrangement information for the second region. Thus, even when the sub pattern is repeatedly arranged in the second region different from the first region, the repetition arrangement information can be generated, and the drawing data can be generated by pasting the drawing pattern of the sub pattern also in the second region, thereby reducing the time for generating the drawing data.

In the first embodiment, the data generation device 100A includes: the display control unit 102 that displays the design data representing a design pattern corresponding to a predetermined exposure pattern on the display unit 193; the reception unit 106 that identifies, from the design pattern, a pattern that is the same as a sub pattern in a specified region using the image of the displayed design pattern; and the first drawing-data generation unit 103 that generates drawing data corresponding to the sub pattern in the specified region and sets the generated drawing data as drawing data corresponding to the identified pattern. The first drawing-data generation unit 103 generates the drawing data corresponding to the pattern identified as the same as the sub pattern by copying the drawing data corresponding to the sub pattern, allocates the drawing data corresponding to the sub pattern on the drawing data coordinates as a part of the drawing data based on the position of the sub pattern in the design pattern, and allocates the drawing data corresponding to the pattern identified as the same as the sub pattern on the drawing data coordinates as another part of the drawing data based on the position of the identified pattern in the design pattern.

The reception unit 106 identifies the same pattern as the main pattern in the specified region, which is specified using the image of the design data that is displayed, from the design pattern, and the data generation device 100A includes the second drawing-data generation unit 104 that generates the drawing data corresponding to the main pattern in the specified region and sets the generated drawing data as the drawing data corresponding to the identified pattern. Then, the second drawing-data generation unit 104 generates drawing data corresponding to the pattern identified as the same as the main pattern by copying the drawing data corresponding to the main pattern, and allocates the drawing data corresponding to the main pattern on the drawing data coordinates as a part of the drawing data based on the position of the main pattern in the design pattern. Furthermore, the second drawing-data generation unit 104 allocates the drawing data corresponding to the pattern identified as the same as the main pattern on the drawing data coordinates as another part of the drawing data based on the position of the identified pattern in the design pattern.

Since the generated drawing data of the sub pattern is allocated on the drawing data coordinates as the drawing data of the pattern identified as the same as the sub pattern, the time required to generate the drawing data can be reduced compared with that in the case where the drawing data of the drawing pattern including the sub pattern arranged repeatedly is generated by converting the design data. Further, since the generated drawing data of the main pattern is allocated on the drawing data coordinates as the drawing data of the pattern identified as the same as the main pattern, the time required to generate the drawing data can be reduced compared with that in the case where the drawing data of the drawing pattern is generated by converting the design data.

In the first embodiment, the case where the user specifies the main pattern and the sub pattern that are repeatedly arranged has been described, but this does not intend to suggest any limitation.

For example, the designer who generated the target pattern knows where the repetition pattern exists in the target pattern. Therefore, the designer may generate the repetition pattern information and the repetition arrangement information based on the target pattern data. In this case, the data generation device 100A may acquire the repetition pattern information and the repetition arrangement information generated by the designer, and may perform the processes of steps S29 to S34 of FIG. 6.

Further, for example, the data generation device 100A may automatically generate the repetition pattern information and the repetition arrangement information by utilizing the fact that the design data has a tree structure of cells. In this case, a cell having a large number of instances or a cell specified as a candidate by the designer (for example, can be specified by a PRIORITY element of OASIS) is extracted as a repetition pattern, and it is checked whether the cell can be copied in units of cells (whether the cell matches a pixel boundary after conversion) and whether the cell does not overlap another pattern (for example, whether an additional wiring pattern is not included) for the locations where the cell appear, and the repetition arrangement information is generated when there is no problem.

In the above embodiment, instead of specifying the main pattern and the sub pattern from the design pattern displayed on the screen, for example, a pattern stored in an external device and for which a drawing pattern has already been generated may be specified as the main pattern or the sub pattern. In this case, the reception unit 106 may search for a region where the same pattern as the main pattern or the sub pattern stored in the external device is repeatedly arranged. Alternatively, the user may issue an instruction to paste a main pattern or a sub pattern stored in an external device, thereby causing the reception unit 106 to generate the repetition arrangement information.

Further, in the above embodiment, an example of data generation in three steps: the sub pattern, the main pattern, and the whole pattern is illustrated, but the exposure data may be generated in more steps. For example, the sub pattern may further include a repetition pattern, and the previously generated drawing data may be pasted to the repetition pattern.

### Second Embodiment

Next, a second embodiment will be described. In the first embodiment, the data generation device 100A acquires the design data generated in advance, but in the second embodiment, the data generation device generates the design data using a function defined by the user to generate the drawing data.

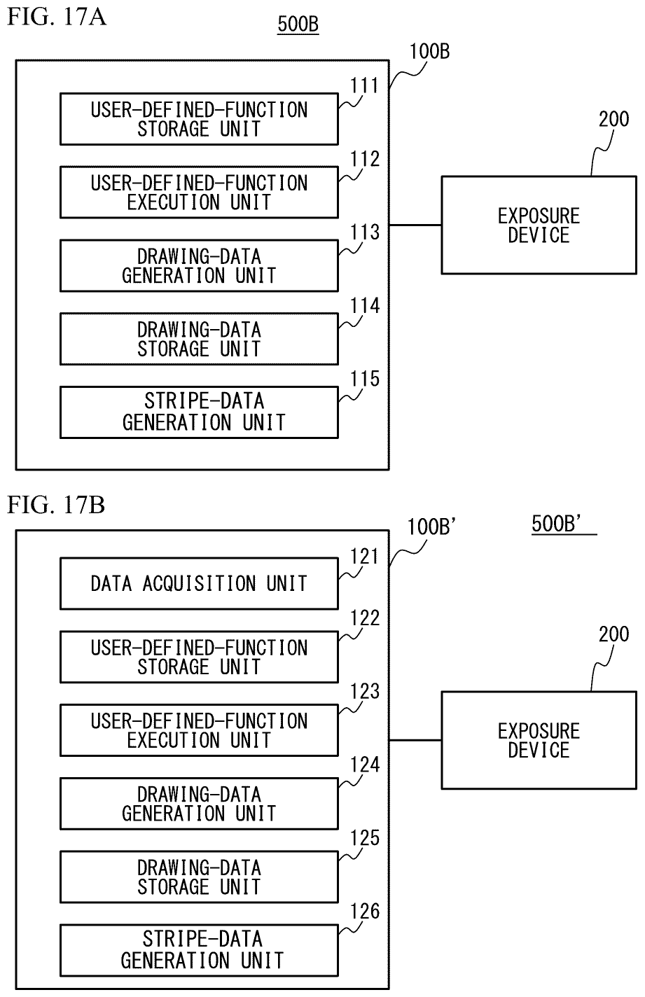

FIG. 17A illustrates a configuration of an exposure system 500B in accordance with the second embodiment. The exposure system 500B includes a data generation device 100B and the exposure device 200. The configuration of the exposure device 200 is the same as that of the first embodiment, and the description thereof will be omitted.

The data generation device 100B in accordance with the second embodiment includes a user-defined-function storage unit 111, a user-defined-function execution unit 112, a drawing-data generation unit 113, a drawing-data storage unit 114, and a stripe-data generation unit 115.

The user-defined-function storage unit 111 stores a function defined by a user (hereinafter referred to as a user-defined function). The user-defined function is a function for generating a design pattern in accordance with a predetermined input/output specification, and may be created by a user of the exposure system as a script file in a high-level scripting language such as the Python language. The form of the user-defined function is not limited to this, and any means such as an external program operated by a predetermined command or a dynamically linked shared library may be used as long as the user can change the behavior without modifying the data generation device. The user-defined function may also call yet another program to generate the design pattern.

The user-defined-function execution unit 112 executes the user-defined function for each section SC to generate a design pattern in the section SC.

The drawing-data generation unit 113 converts the design pattern generated by the user-defined-function execution unit 112 for each section SC into a drawing pattern, and generates drawing data for each section SC. The generated drawing data is stored in the drawing-data storage unit 114. The drawing-data storage unit 114 stores the drawing data (bitmap file) for each section SC.

The stripe-data generation unit 115 generates stripe data by combining drawing data stored in the drawing-data storage unit 114.

Normally, the drawing data is generated by generating a target pattern, converting the target pattern into a design pattern, and converting the design pattern into a drawing pattern. However, in the second embodiment, since the design pattern is generated as needed by a user-defined function, it is not necessary to prepare target pattern data and design data in advance. This can reduce the time required to complete the generation of the drawing data.

### Variation

FIG. 17B illustrates a configuration of an exposure system 500B′ in accordance with a variation of the second embodiment. The exposure system 500B′ includes a data generation device 100B′ and the exposure device 200. The configuration of the exposure device 200 is the same as that of the first embodiment, and the description thereof will be omitted.

In the variation of the second embodiment, the data generation device 100B′ includes a data acquisition unit 121, a user-defined-function storage unit 122, a user-defined-function execution unit 123, a drawing-data generation unit 124, a drawing-data storage unit 125, and a stripe-data generation unit 126.

The data acquisition unit 121 acquires design data. The user-defined-function storage unit 122 stores a user-defined function. The user-defined function in the variation is a function for performing a predetermined process (for example, execution of OPC, readjustment of OPC, or the like) on the design pattern of each section SC extracted from the design data.

The user-defined-function execution unit 123 sequentially extracts design patterns corresponding to the respective sections SC from the design pattern acquired by the data acquisition unit 121, performs predetermined processing on the extracted design patterns (processes the design patterns) by executing the user-defined function on the extracted design patterns, and outputs the processed design patterns to the drawing data generation unit 124 as design patterns for the sections SC.

The drawing-data generation unit 124 converts the design pattern input from the user-defined-function execution unit 123 into a drawing pattern to generate drawing data of the section SC, and stores the drawing data in the drawing-data storage unit 125.

The stripe-data generation unit 126 generates stripe data by combining the drawing data for each section SC stored in the drawing data storage unit 125.

In the variation of the second embodiment, when the drawing data is generated, a predetermined process or the like can be performed on the design data by using the user-defined function, and thus the degree of freedom in generating the drawing data is improved.

### Third Embodiment

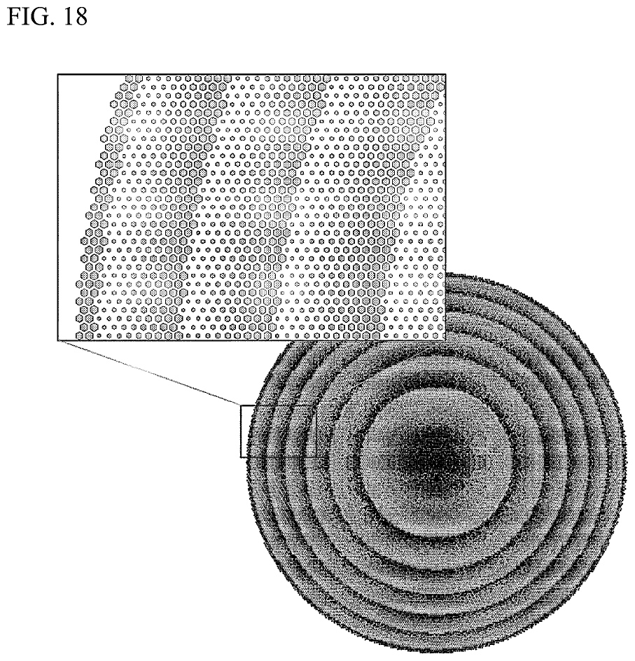

In a third embodiment, a case of generating drawing data used for manufacturing a planar optical element called a metasurface will be described using a metalens as an example. As illustrated in FIG. 18, the metalens is a lens having a structure in which a pattern finer than the wavelength of target light is arranged on a flat plate.

The drawing data of the drawing pattern for manufacturing the metalens can be generated by performing OPC on the target pattern data to obtain design data and then converting the design data into the drawing data. However, the file size of the design data representing the design pattern obtained by performing the OPC on the target pattern increases as the diameter of the metalens increases. For example, the file size of the design data for a diameter of 1 mm is only about several tens of MB, whereas the file size for a diameter of 180 mm is several hundreds of GB. Although the use of the drawing data generation described in the second embodiment would eliminate the need to create a huge file, generating drawing data from design data with such a large file size could require weeks or months of time, for example.

In the third embodiment, drawing data of a drawing pattern is generated without generating design data representing the design pattern corresponding to the exposure pattern of the metasurface.

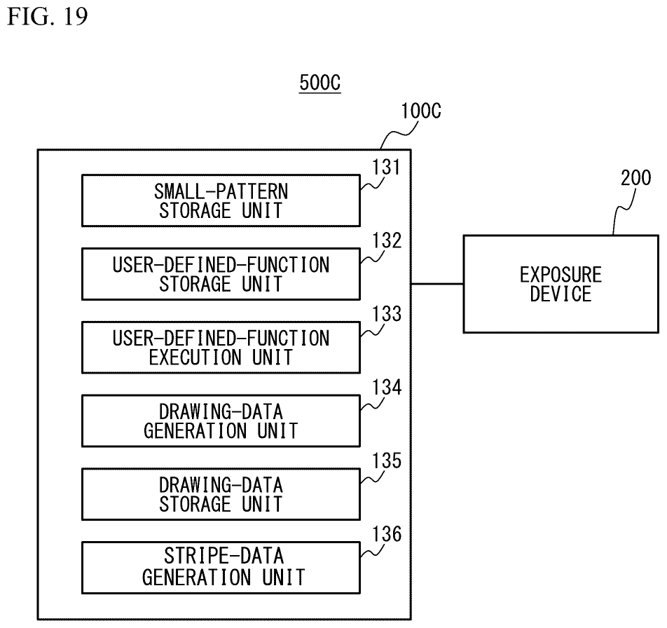

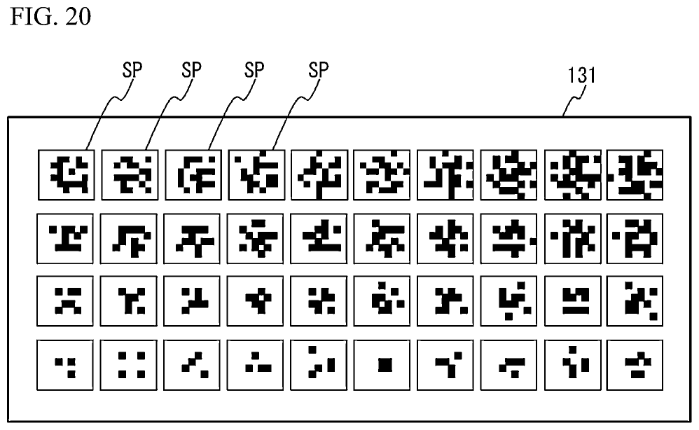

FIG. 19 illustrates a configuration of an exposure system 500C in accordance with the third embodiment. The exposure system 500C includes a data generation device 100C and the exposure device 200. The configuration of the exposure device 200 is the same as that of the first embodiment, and the description thereof will be omitted.

The data generation device 100C of the third embodiment includes a small-pattern storage unit 131, a user-defined-function storage unit 132, a user-defined-function execution unit 133, a drawing-data generation unit 134, a drawing-data storage unit 135, and a stripe-data generation unit 136.

As illustrated in FIG. 20, the small pattern storage unit 131 stores drawing data representing a plurality of drawing patterns (to be referred to as small patterns SP hereinafter) each having a size smaller than that of the drawing pattern of the entire metalens.

The user-defined-function storage unit 132 stores functions defined by the user. In the third embodiment, the drawing data for each section SC is generated by combining and pasting the small patterns SP in each section SC. Therefore, the user-defined function in the third embodiment is a function that outputs at least information for identifying a small pattern to be pasted in the section SC for which drawing data is to be generated among the small patterns SP stored in the small-pattern storage unit 131 and the position at which the small pattern is pasted in each section SC. The small pattern SP may be pasted according to another rule instead of the user-defined function.

The user-defined-function execution unit 133 pastes the small pattern SP in each section SC by executing the user-defined function for each section SC to generate drawing data for each section SC. The generated drawing data for each section SC is stored in the drawing-data storage unit 135.

The stripe-data generation unit 136 generates stripe data by combining the drawing data of each section SC stored in the drawing-data storage unit 135.

As described above, in the third embodiment, since the drawing data of each section SC is generated by combining and pasting the small patterns SP in each section SC, the time required to generate the drawing data representing the drawing pattern of the metasurface can be reduced compared with that in the case where the drawing pattern is generated by converting the design pattern. The third embodiment may be applied not only to generation of the drawing pattern of a metalens but also to generation of other drawing patterns. Further, the stripe data may be directly generated without generating the drawing data of each section SC. In this case, the data generation time can be reduced by omitting the data generation at the intermediate stage.

The processing functions described above can be implemented by a computer. In this case, a program describing the processing contents of the functions to be included in the processing device is provided. The program is executed by the computer, and thus the processing functions are implemented on the computer. The program describing the processing contents may be recorded in a computer-readable storage medium (excluding a carrier wave).

When the program is distributed, the program is sold in, for example, a form of a portable storage medium such as a digital versatile disc (DVD) or a compact disc read only memory (CD-ROM) in which the program is recorded. The program may be stored in a storage device of a server computer, and the program may be transferred from the server computer to another computer via a network.

A computer that executes the program stores the program recorded in a portable storage medium or the program transferred from the server computer in its own storage device, for example. The computer reads the program from its storage device and executes processing according to the program. The computer may read the program directly from the portable storage medium and execute the processing according to the program. Further, the computer can also sequentially execute processing according to the received program each time the program is transferred from the server computer.

In the above-described embodiment, the process of modifying or adding a figure in an existing layer is performed, but a process of adding a new layer having a different transmittance may be performed. For example, a process of improving the imaging performance by adding a phase shifter to the periphery of the pattern can be included. The transmittance of such a phase shifter is typically about 6%. The optical path length of the phase shifter portion is determined so that the phase of the light passing through the phase shifter portion and the phase of the light passing through the transmission portion (the reflection portion in the case of the reflection type) are inverted with respect to each other. Since the transmittance given here is used for calculation, it is not necessary to match the transmittance with the transmittance of a material that can be used in actual photomask manufacturing, and a freely selected value may be set.

At least one or some of the constituent components of each of the above-described embodiments can be appropriately combined with at least another one of the constituent components of each of the above-described embodiments. Some of the constituent components of the above-described embodiments may not be used. As long as the law permits, the disclosures of all the publications and U.S. patents cited in the above embodiments are incorporated herein by reference.

The above-described embodiment is a preferred example of the present disclosure. However, the present disclosure is not limited to this, and various modifications can be made without departing from the scope of the present disclosure.

What is claimed is:

1. A method of generating drawing data representing a drawing pattern to be formed by a spatial light modulator to form a predetermined exposure pattern on a substrate with exposure light via the spatial light modulator, the method being implemented by a computer, the method comprising:
generating design data representing a design pattern corresponding to the predetermined exposure pattern by using a function defined by a user; and
generating the drawing data of the drawing pattern by converting the design data.

2. The method according to claim 1, wherein the generating of the design data includes performing the function defined by the user for each location in the substrate.

3. The method according to claim 1, wherein the generating of the design data includes, for each location in the substrate, performing the function defined by the user on a first design pattern that is generated in advance.

4. A method of generating drawing data representing a drawing pattern to be formed by a spatial light modulator to form a predetermined exposure pattern on a substrate with exposure light via the spatial light modulator, the method being implemented by a computer, the method comprising:
acquiring drawing data of each of a plurality of different drawing patterns that are generated in advance and have a size smaller than the drawing pattern; and
generating the drawing data of the drawing pattern by arranging the drawing data of the plurality of different drawing patterns in accordance with a predetermined rule.

5. The method according to claim 4, wherein the predetermined rule is a function defined by a user.

6. A drawing data generation device that generates drawing data representing a drawing pattern to be formed by a spatial light modulator to form a predetermined exposure pattern on a substrate with exposure light via the spatial light modulator, the drawing data generation device comprising:
a first generation unit configured to generate design data representing a design pattern corresponding to the predetermined exposure pattern by using a function defined by a user; and
a second generation unit configured to generate the drawing data of the drawing pattern by converting the design data.

7. A drawing data generation device that generates drawing data representing a drawing pattern to be formed by a spatial light modulator to form a predetermined exposure pattern on a substrate with exposure light via the spatial light modulator, the drawing data generation device comprising:
an acquisition unit configured to acquire drawing data of each of a plurality of different drawing patterns that are generated in advance and have a size smaller than the drawing pattern; and
a generation unit configured to generate the drawing data of the drawing pattern by arranging the drawing data of the plurality of different drawing patterns in accordance with a predetermined rule.

8. A non-transitory computer-readable storage medium storing a drawing data generation program that executes the method according to claim 1.

9. A non-transitory computer-readable storage medium storing a drawing data generation program that executes the method according to claim 4.

10. A method of generating drawing data representing a drawing pattern to be formed by a spatial light modulator to form a predetermined exposure pattern on a substrate with exposure light via the spatial light modulator, the method being implemented by a computer, the method comprising:
displaying design data representing a design pattern corresponding to the predetermined exposure pattern;
identifying, from the design pattern, a second partial design pattern that is the same as a first partial design pattern in a specified region that is specified using an image of the designed data that has been displayed;
generating first partial drawing data corresponding to the first partial design pattern in the specified region; and
setting the first partial drawing data that has been generated as second partial drawing data corresponding to the second partial design pattern that has been specified.

11. The method according to claim 10,
wherein the second partial drawing data corresponding to the second partial design pattern is generated by copying the first partial drawing data corresponding to the first partial design pattern,
wherein the first partial drawing data corresponding to the first partial design pattern is allocated as a part of the drawing data on drawing data coordinates based on a position of the first partial design pattern in the design pattern, and
wherein the second partial drawing data corresponding to the second partial design pattern is allocated as another part of the drawing data on the drawing data coordinates based on a position of the second partial design pattern in the design pattern.

12. The method according to claim 10, wherein the identifying is performed using an image of the design data that has been displayed.

13. The method according to claim 10, wherein the identifying includes searching for a region having the same pattern as a design pattern in the specified region from the design pattern.

14. The method according to claim 10,
wherein the design pattern includes a second pattern repeatedly arranged, the second pattern including a plurality of first patterns repeatedly arranged, and
wherein the specified region is at least one of a region in the design pattern where the first pattern is located or a region in the design pattern where the second pattern is located.
